(19) United States
(12) Patent Application Publication
(10) Pub. No.: US 2024/0113220 A1
(43) Pub. Date: Apr. 4, 2024

(54) TECHNOLOGIES FOR TRANSISTORS WITH A THIN-FILM FERROELECTRIC

(71) Applicant: Intel Corporation, Santa Clara, CA (US)

(72) Inventors: Arnab Sen Gupta, Hillsboro, OR (US); Ian Alexander Young, Olympia, WA (US); Dmitri Evgenievich Nikonov, Beaverton, OR (US); Marko Radosavljevic, Portland, OR (US); Matthew V. Metz, Portland, OR (US); John J. Plombon, Portland, OR (US); Raseong Kim, Portland, OR (US); Uygar E. Avci, Portland, OR (US); Kevin P. O'Brien, Portland, OR (US); Scott B. Clendenning, Portland, OR (US); Jason C. Retasket, Beaverton, OR (US); Shriram Shivaraman, Hillsboro, OR (US); Dominique A. Adams, Portland, OR (US); Carly Rogan, North Plains, OR (US); Punyashloka Debashis, Hillsboro, OR (US); Brandon Holybee, Portland, OR (US); Rachel A. Steinhardt, Beaverton, OR (US); Sudarat Lee, Hillsboro, OR (US)

(73) Assignee: Intel Corporation, Santa Clara, CA (US)

(21) Appl. No.: 17/958,094

(22) Filed: Sep. 30, 2022

(51) Int. Cl. H01L 29/78; H01L 21/02; H01L 29/20; H01L 29/24; H01L 29/51; H01L 29/66; H01L 29/76

(52) U.S. Cl. CPC H01L 29/78391; H01L 21/0254; H01L 21/02568; H01L 21/0262; H01L 29/2003; H01L 29/24; H01L 29/516; H01L 29/66522; H01L 29/6684; H01L 29/66969; H01L 29/7606

(57) ABSTRACT

Technologies for a transistor with a thin-film ferroelectric gate dielectric are disclosed. In the illustrative embodiment, a transistor has a thin layer of scandium aluminum nitride (ScₓAl₁₋ₓN) ferroelectric gate dielectric. The channel of the transistor may be, e.g., gallium nitride or molybdenum disulfide. In one embodiment, the ferroelectric polarization changes when voltage is applied and removed from a gate electrode, facilitating switching of the transistor at a lower applied voltage. In another embodiment, the ferroelectric polarization of a gate dielectric of a transistor changes when the voltage is past a positive threshold value or a negative threshold value. Such a transistor can be used as a one-transistor memory cell.

### BACKGROUND

Transistors are ubiquitous devices present in virtually all electronic devices. As the density of transistors continues to increase, the power dissipated by the transistors needs to be addressed. The power dissipation of a transistor can be reduced in several ways, such as reducing leakage current and reducing the threshold voltage of the transistor.

A typical transistor can maintain its state when a voltage is maintained at a gate electrode. However, a ferroelectric field-effect transistor (FEFET) can maintain its state based on a state of a ferroelectric layer in the transistor. FEFETs typically have a relatively high threshold voltage and a corresponding relatively high leakage current.

### BRIEF DESCRIPTION OF THE DRAWINGS

FIG. 1 is a top view of a transistor with a gate dielectric that is ferroelectric.

FIG. 2 is a cross-sectional side view of the transistor of FIG. 1.

FIG. 3 is a cross-sectional side view of one embodiment of a transistor with a gate dielectric that is ferroelectric.

FIG. 4 is a perspective view of a transistor with fins and a gate dielectric that is ferroelectric.

FIG. 5 is a perspective view of a transistor with a gate-all-around dielectric that is ferroelectric.

FIG. 6 is a simplified flow diagram of at least one embodiment of a method for creating a transistor with a gate dielectric that is ferroelectric.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIGS. 9A-9D are perspective views of example planar, FinFET, gate-all-around, and stacked gate-all-around transistors.

FIG. 10 is a cross-sectional side view of an integrated circuit device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Ferroelectric field-effect transistors (FEFETs) can use the spontaneous polarization in a ferroelectric material to apply an electric displacement to raise or lower a gate voltage above or below a threshold voltage. The orientation of the spontaneous polarization in the ferroelectric material can be changed by the application of an electric field to a gate of the transistor, allowing the transistor to be used as a memory cell. In some embodiments disclosed herein, a FEFET has a dielectric of ScₓA₁₋ₓN with a GaN or MoS₂ thin film channel.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate, and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

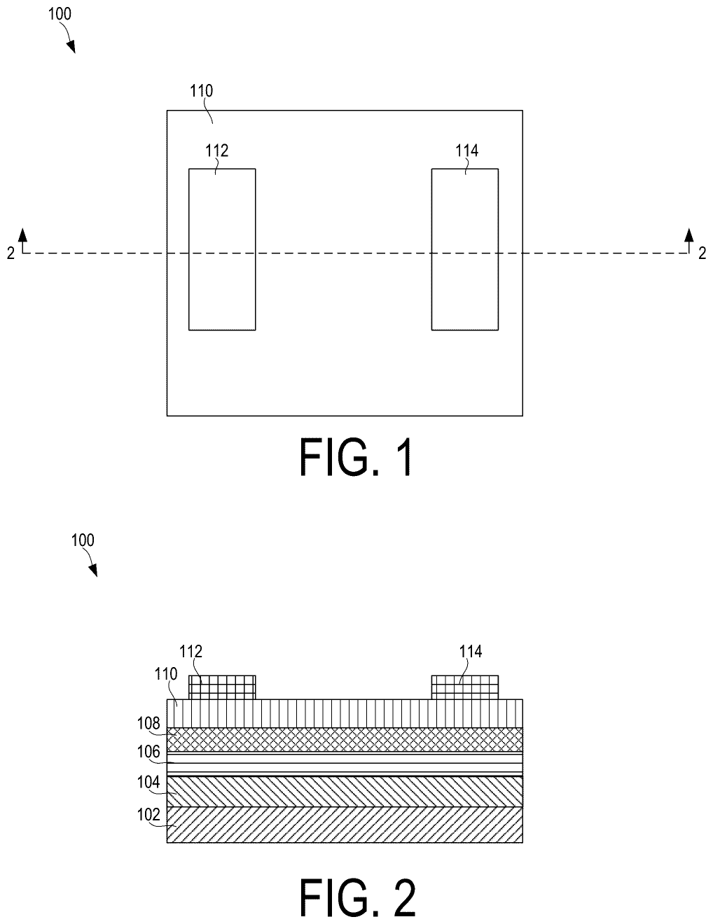

Referring now to FIGS. 1 and 2, in one embodiment, a transistor 100 has a substrate 102, a buffer layer 104, a gate electrode 106, a ferroelectric layer 108, a channel 110, a source electrode 112, and a drain electrode 114. FIG. 1 shows a top-down view of the transistor 100, and FIG. 2 shows a cross-sectional view of the transistor 100.

In use, a voltage can be applied to the gate electrode 106, which causes an electric field to be applied to the ferroelectric layer 108 and to the channel 110. In the illustrative embodiment, if the applied voltage causes an electric field above a coercive field, the direction of the spontaneous polarization of the ferroelectric material can switch. The electric displacement of the ferroelectric material is the spontaneous polarization of the ferroelectric when no electric field is applied by the ferroelectric layer 108. Under the applied field from the voltage of the gate electrode 106, the electric displacement of the ferroelectric material increases. As a result, the electric displacement applied to the channel 110 is affected by the polarization state of the ferroelectric material of the dielectric 108, and, therefore, the current through the channel 110 is affected by the polarization state of the ferroelectric material of the dielectric 108. The transistor 100 and other ferroelectric transistors described herein can be used to facilitate low-threshold switching, single transistor memory, and compute-in-memory.

The threshold voltage of the transistor 100 depends on the ferroelectric layer 108 material as well as the channel 110 thickness and doping concentration. In the illustrative embodiment, the threshold voltage of the transistor 100 is about 250 millivolts applied to the gate electrode 106, with the polarization of the ferroelectric material of the ferroelectric layer 108 increasing the electric displacement applied to the channel 110. In other embodiments, the threshold voltage of the transistor 100 may be any suitable value, such as 0.2-5 volts, depending on the materials used.

In some embodiments, the polarization of the ferroelectric layer 108 switches all at once in a few picoseconds. In other embodiments, the ferroelectric layer 108 may have multiple domains that may switch at different applied electric fields (and, therefore, at different times). In such embodiments, the ferroelectric layer 108 may have multiple stable states that can be set by applying a particular voltage to the gate electrode 106. Such a transistor 100 can act as a multi-level memory or like an analog memory.

In the illustrative embodiment, the substrate 102 is silicon. A buffer layer 104 may be present in some embodiments, which other layers may adhere to better than a silicon substrate 102. In some embodiments, the substrate 102 may be a different material, such as germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate 102, is gallium nitride, and the various layers, such as the gate electrode 106, can be formed directly on the substrate 102 without a buffer layer 104. In some embodiments, the structure of the transistor (or the transistors 400, 500 discussed below) may be formed on a separate substrate, such as a gallium nitride substrate, and then transferred to the substrate 102 using wafer bonding. Either chiplets or components for an entire wafer may be transferred in such a manner.

The gate electrode 106 may be any suitable conductive material, such as titanium nitride or platinum. In the illustrative embodiment, the ferroelectric layer 108 is ScₓAl₁₋ₓN. The value for x in the formula may be any suitable value, such as 0.1-0.5. The channel 110 may be, e.g., gallium nitride (GaN) or molybdenum disulfide (MoS₂). The source electrode 112 and/or drain electrode 114 may be any suitable material, such as titanium nitride, gold, or other conductive material.

The channel 110 may include a source region under the source electrode 112, and a drain region under the drain electrode 114 (not explicitly shown in FIGS. 1 and 2). The source region and drain region may be doped. For example, for an n-doped channel 110, the source region and drain region may be n-doped, and for a p-doped channel 110, the source region and drain region may be p-doped. In the illustrative embodiment, the transistor 100 is symmetric, and there is no functional distinction between the source region and the drain region. The source/drain regions may be formed using either an implantation/diffusion process or an etching/deposition process. In the former process, dopants such as lanthanum, boron, aluminum, antimony, phosphorous, or arsenic may be ion-implanted into the channel material to form the source/drain regions. An annealing process that activates the dopants and causes them to diffuse further into the channel 110 may follow the ion implantation process. In the latter process, the channel 110 may first be etched to form recesses at the locations of the source regions. An epitaxial deposition process may then be carried out to fill the recesses with material that is used to fabricate the source/drain regions.

In the illustrative embodiment, some or all of the various layers and components of the transistor 100 are in the form of a thin-films deposited on the substrate 102 or the buffer layer 104. The thin-film layers may be deposited in any suitable manner. For example, the ferroelectric layer 108 may be deposited as a thin film using, e.g., atomic layer deposition, molecular beam epitaxy, pulsed laser deposition, physical vapor deposition, sputter deposition, etc. The thickness of the various layers (e.g., the gate electrode 106, the ferroelectric layer 108, the channel 110, etc.) may be any suitable value, such as 0.5-200 nanometers. In some embodiments, the ferroelectric layer 108 may have a thickness of, e.g., 1-50 nanometers, and the channel 110 may have a thickness of, e.g., 2-100 nanometers.

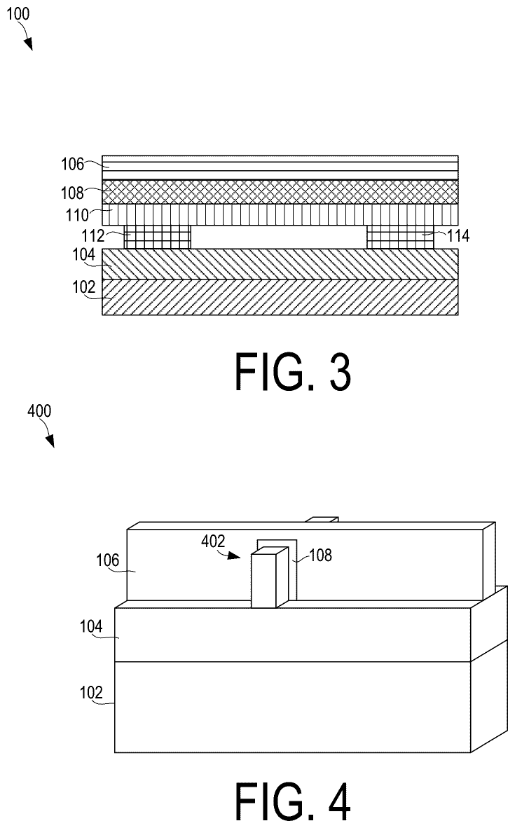

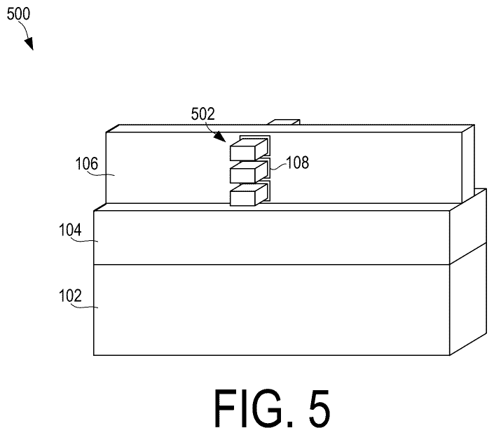

In the embodiment shown in FIGS. 1 and 2, the transistor 100 has a bottom gate and top contact configuration. In other embodiments, the transistor 100 may be filled, with a bottom contact configuration and a top gate, as shown in FIG. 3. Other configurations are possible as well. For example, FIG. 4 shows a fin field-effect transistor (finFET), with fins 402 extending along the buffer layer 104, with the gate electrode 106 covering the fin 402, separated by the ferroelectric layer 108. Each end of the fin 402 may be doped to be source/drain regions, and a center area of the fin 402 by the gate electrode 106 and the ferroelectric layer 108 may be doped to be the channel. In another example, FIG. 5 shows a gate-all-around configuration, with several fins 502 acting as the source region and the drain region surrounded by the gate electrode 106 and the ferroelectric layer 108.

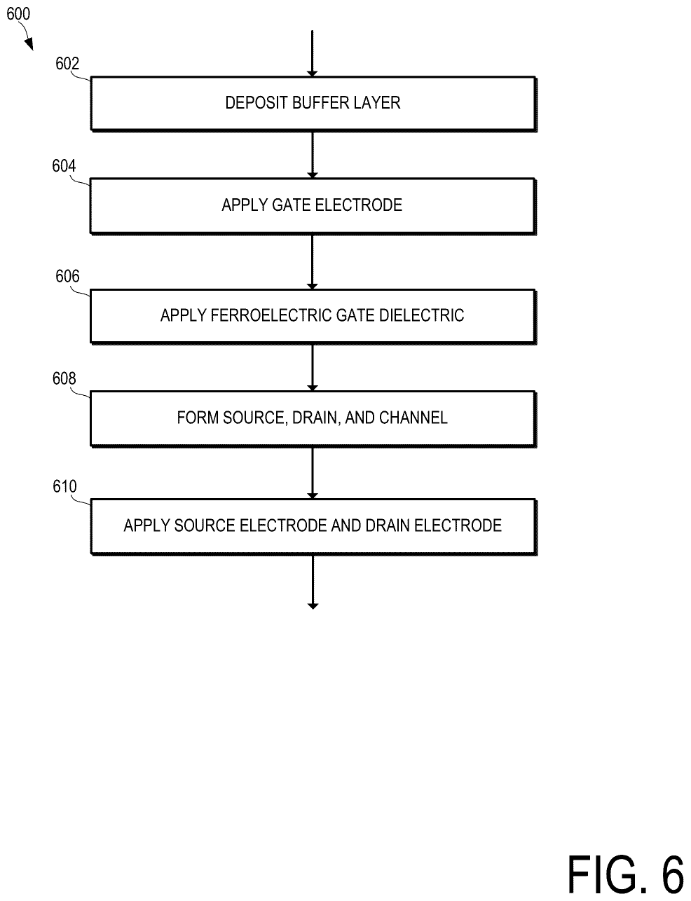

Referring now to FIG. 6, in one embodiment, a flowchart for a method 600 for creating a transistor (such as transistor 100, 400, or 500) is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, causes the machine to perform some or all of the steps of the method 600. The method 600 may use any suitable set of techniques that are used in semiconductor processing, such as chemical vapor deposition, atomic layer deposition, physical vapor deposition, molecular beam epitaxy, pulsed laser deposition, layer transfer, photolithography, ion implantation, dry etching, wet etching, thermal treatments, etc.

The method 600 begins in block 602, in which the buffer layer 104 is deposited on the substrate 102. The buffer layer 104 may be deposited in any suitable manner, such as chemical vapor deposition, atomic layer deposition, physical vapor deposition, molecular beam epitaxy, pulsed laser deposition, etc. In some embodiments, the buffer layer 104 is deposited using layer transfer.

In block 604, the gate electrode 106 is applied. In the illustrative embodiment, the gate electrode 106 is titanium nitride. In other embodiments, the gate electrode 106 may be another conductive material, such as platinum.

In block 606, a ferroelectric gate dielectric 108 is applied. In the illustrative embodiment, the gate dielectric 108 is scandium aluminum nitride (ScₓAl₁₋ₓN). The ferroelectric gate dielectric 116 may be applied using, e.g., atomic layer deposition.

In block 608, the channel 110 is formed on the ferroelectric layer 108. The channel 110 may be, e.g., gallium nitride or molybdenum disulfide. The channel 110 may be doped to form a source region and a drain region, such as by using ion implantation. The source region and drain region may be relatively heavily doped, and the rest of the channel 110 may be relatively lightly doped. In some embodiments, the channel 110 may be doped with the same carrier type as the source region and drain region. For example, the channel 110 may be n-doped and the source region and drain region may be n-doped, or all three may be p-doped. In other embodiments, the channel 110 may be doped with the opposite carrier type as the source region and drain region.

In block 610, source electrode 112 and drain electrode 114 are applied. The source electrode 112 and drain electrode 114 may be any suitable material, such as titanium nitride, platinum, iridium, or other metal, polysilicon, a metallic perovskite, etc. The source electrode 112 and drain electrode 114 may be applied using, e.g., photolithography and physical vapor deposition.

It should be appreciated that the method 600 is one of many possible embodiments of manufacturing the transistor 100. Different approaches or orders of steps are envisioned as well. For example, the ferroelectric gate dielectric 108 and gate electrode 106 may be applied before doping the source region and drain region, creating a self-aligned gate. The steps of the method 600 may be done in a different order or the method 600 may include different steps for, e.g., a finFET 400 or a gate-all-around transistor 500. It should be appreciated that a complete manufacturing process of an integrated circuit that includes the transistor 100 may include steps not shown in the method 600, such as cleaning, surface passivation, creating interconnects, packaging, etc. In some embodiments, the transistor 100 may be formed on one substrate (such as gallium nitride) and transferred using wafer bonding to a wafer or die with another substrate, such as silicon.

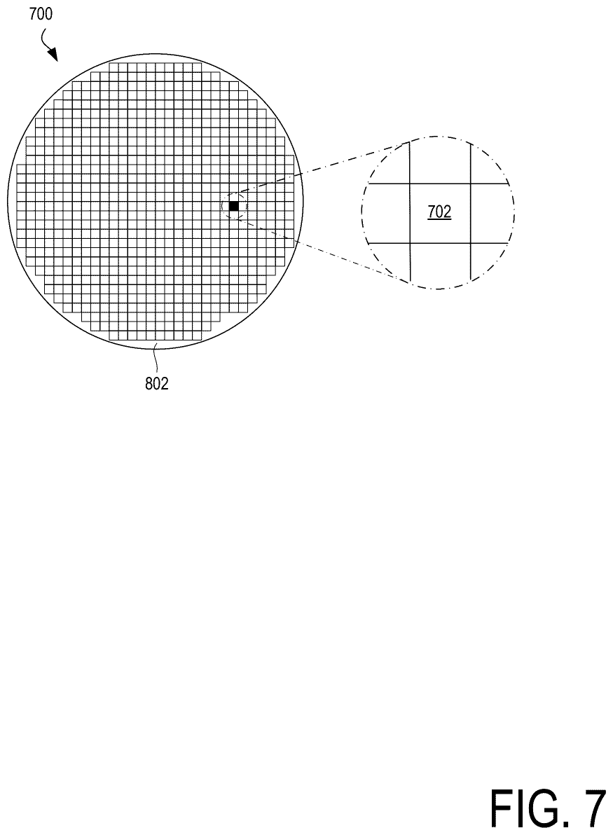

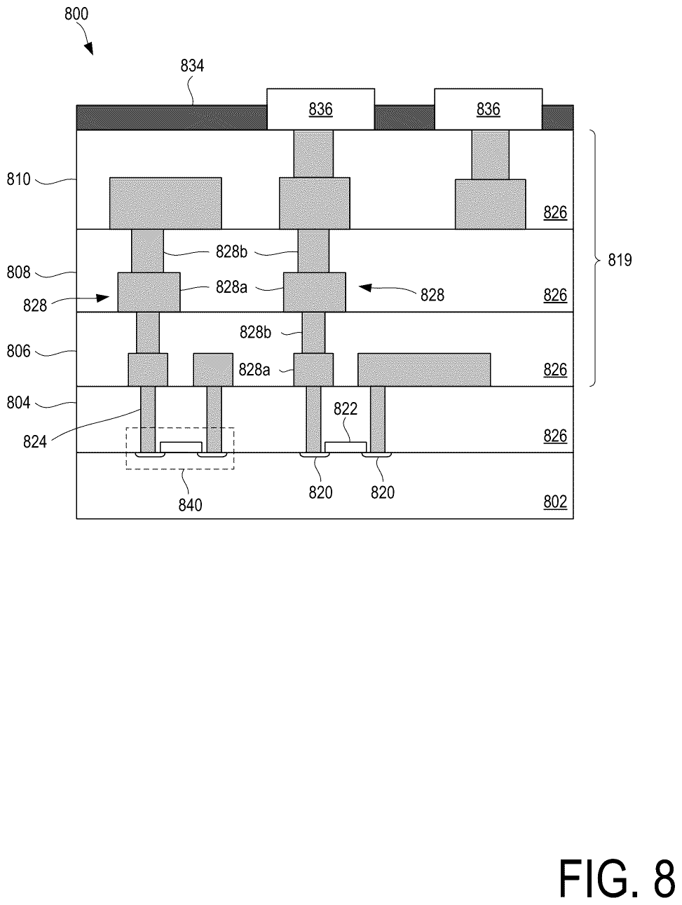

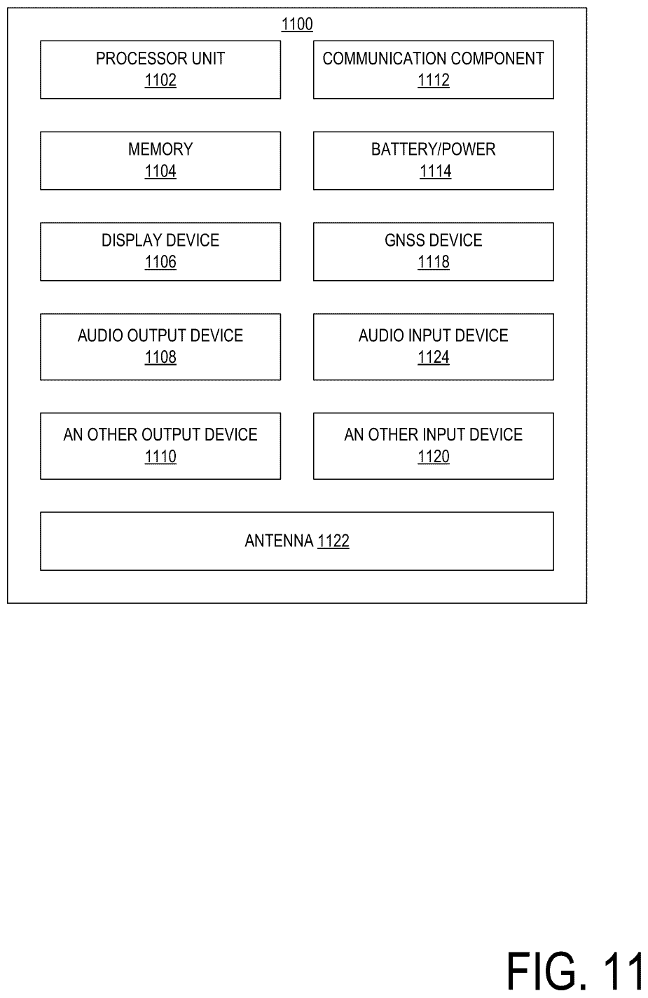

FIG. 7 is a top view of a wafer 700 and dies 702 that may include any of the transistors 100, 400, 500 disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include any of the transistors 100, 400, 500 disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1102 of FIG. 11) or other logic that is configured to store information in the memory devices or execute instructions stored in the memory array. Various ones of the transistors 100, 400, 500 disclosed herein may be manufactured using a die-to-wafer assembly technique in which some components are attached to a wafer 700 that include other components, and the wafer 700 is subsequently singulated.

FIG. 8 is a cross-sectional side view of an integrated circuit device 800 that may include any of the transistors 100, 400, 500 disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

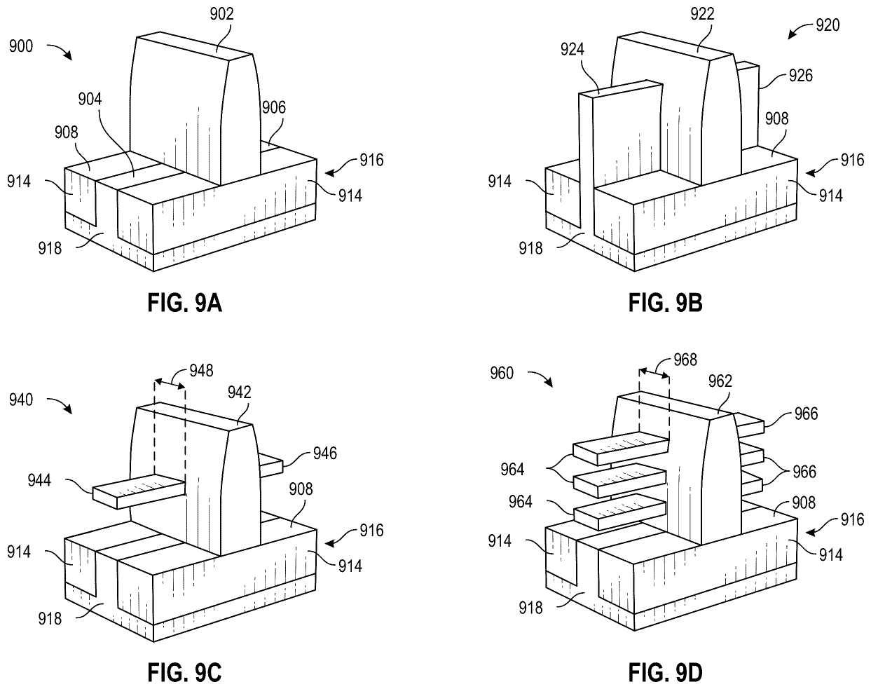

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 928. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 928.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extends from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

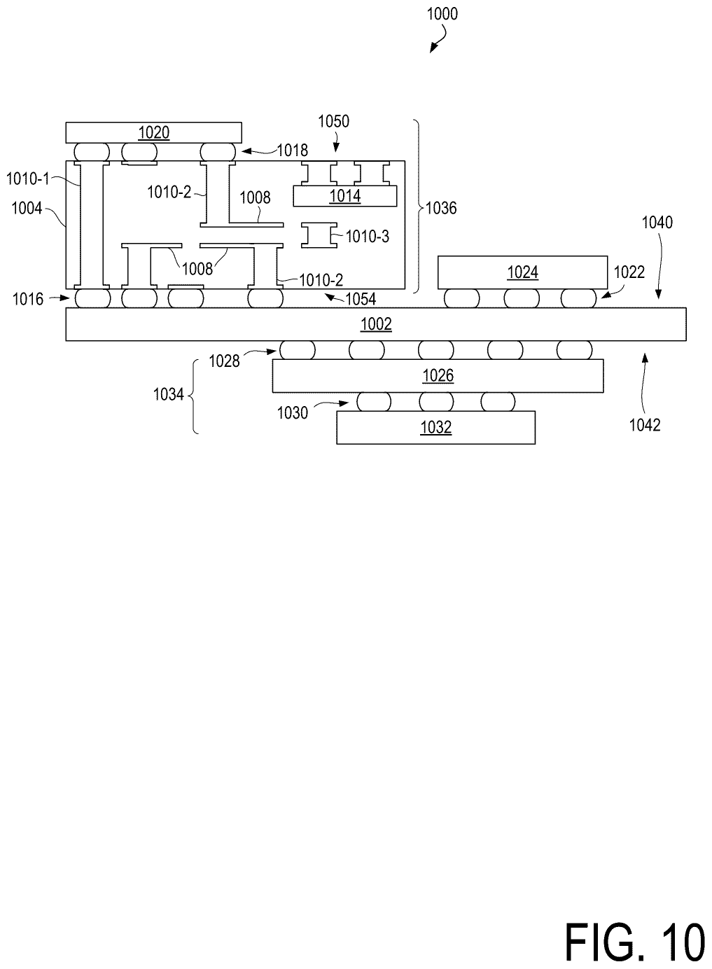

FIG. 10 is a cross-sectional side view of an integrated circuit device assembly 1000 that may include any of the transistors 100, 400, 500 disclosed herein. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may include any suitable ones of the embodiments of the transistors 100, 400, 500 disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the transistors 100, 400, 500 disclosed herein. For example, any suitable ones of the components of the electrical device 1100 may include one or more of the integrated circuit device assemblies 1000, integrated circuit components 1020, integrated circuit devices 800, or integrated circuit dies 702 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include an other output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include an other input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

### EXAMPLES

Illustrative examples of the technologies disclosed herein are provided below. An embodiment of the technologies may include any one or more, and any combination of, the examples described below.

Example 1 includes a device comprising a source region; a drain region; a channel between the source region and the drain region; a gate electrode; and a gate dielectric between the gate electrode and the channel, wherein the gate dielectric is ferroelectric, wherein the gate dielectric comprises scandium, aluminum, and nitrogen.

Example 2 includes the subject matter of Example 1, and wherein the channel comprises gallium and nitrogen.

Example 3 includes the subject matter of any of Examples 1 and 2, and wherein the channel comprises molybdenum and sulfur.

Example 4 includes the subject matter of any of Examples 1-3, and wherein the device comprises a transistor, wherein the transistor comprises the source region, the drain region, the channel, the gate dielectric, and the gate electrode, wherein a threshold voltage of the transistor is less than 0.5 volts.

Example 5 includes the subject matter of any of Examples 1-4, and wherein the gate electrode has a work function such that the gate dielectric switches polarization in response to a change of voltage applied to the gate electrode from above a threshold voltage of the device to zero voltage.

Example 6 includes the subject matter of any of Examples 1-5, and wherein the gate electrode has a work function such that the gate dielectric has two stable polarization states when zero voltage is applied to the gate electrode.

Example 7 includes a memory device comprising the device in Example 6, wherein the two stable polarization states of the gate dielectric is used to store a memory bit.

Example 8 includes the subject matter of Example 7, and wherein the device comprises a transistor, wherein the transistor comprises the source region, the drain region, the channel, the gate dielectric, and the gate electrode, wherein the transistor is a FinFET, a gate-all-around transistor, or a stacked gate-all-around-transistor.

Example 9 includes a processor comprising the device of any of Examples 1-8.

Example 10 includes a system comprising the processor of Example 9 and one or more memory devices.

Example 11 includes a device comprising a transistor, the transistor comprising a gate dielectric, wherein the gate dielectric is ferroelectric, wherein the gate dielectric comprises scandium, aluminum, and nitrogen.

Example 12 includes the subject matter of Example 11, and wherein a threshold voltage of the transistor is less than 0.5 volts.

Example 13 includes the subject matter of any of Examples 11 and 12, and wherein the transistor comprises a channel, wherein the channel comprises gallium and nitrogen.

Example 14 includes the subject matter of any of Examples 11-13, and wherein the transistor comprises a channel, wherein the channel comprises molybdenum and sulfur.

Example 15 includes the subject matter of any of Examples 11-14, and wherein the transistor comprises a gate electrode, wherein the gate electrode has a work function such that the gate dielectric switches polarization in response to a change of voltage applied to the gate electrode from above a threshold voltage of the device to zero voltage.

Example 16 includes the subject matter of any of Examples 11-15, and wherein the transistor comprises a gate electrode, wherein the gate electrode has a work function such that the gate dielectric has two stable polarization states when zero voltage is applied to the gate electrode.

Example 17 includes a memory device comprising the device in Example 16, wherein the two stable polarization states of the gate dielectric is used to store a memory bit.

Example 18 includes the subject matter of Example 17, and wherein the transistor is a FinFET, a gate-all-around transistor, or a stacked gate-all-around-transistor.

Example 19 includes a processor comprising the device of any of Examples 1-11.

Example 20 includes a system comprising the processor of Example 19 and one or more memory devices.

Example 21 includes a device comprising a transistor comprising a source region; a drain region; a channel between the source region and the drain region; a gate electrode; and a gate dielectric between the gate electrode and the channel, wherein the gate dielectric comprises scandium, aluminum, and nitrogen, wherein a threshold voltage of the transistor is less than 0.5 volts.

Example 22 includes the subject matter of Example 21, and wherein the channel comprises gallium and nitrogen.

Example 23 includes the subject matter of any of Examples 21 and 22, and wherein the channel comprises molybdenum and sulfur.

Example 24 includes the subject matter of any of Examples 21-23, and wherein the gate electrode has a work function such that the gate dielectric switches polarization in response to a change of voltage applied to the gate electrode from above the threshold voltage to zero voltage.

Example 25 includes the subject matter of any of Examples 21-24, and wherein the gate electrode has a work function such that the gate dielectric has two stable polarization states when zero voltage is applied to the gate electrode.

Example 26 includes a memory device comprising the device in Example 25, wherein the two stable polarization states of the gate dielectric is used to store a memory bit.

Example 27 includes the subject matter of Example 26, and wherein the transistor is a FinFET, a gate-all-around transistor, or a stacked gate-all-around-transistor.

Example 28 includes a processor comprising the device of any of Examples 21-27.

Example 29 includes a system comprising the processor of Example 28 and one or more memory devices.

Example 30 includes a method comprising depositing a channel of a transistor; depositing a gate dielectric of the transistor, wherein the gate dielectric and the channel are adjacent, wherein the gate dielectric is ferroelectric, wherein the gate dielectric comprises scandium, aluminum, and nitrogen; and depositing a gate electrode of the transistor, wherein the gate electrode and the gate dielectric are adjacent.

Example 31 includes the subject matter of Example 30, and wherein a threshold voltage of the transistor is less than 0.5 volts.

Example 32 includes the subject matter of any of Examples 30 and 31, and wherein the channel comprises gallium and nitrogen.

Example 33 includes the subject matter of any of Examples 30-32, and wherein the channel comprises molybdenum and sulfur.

Example 34 includes the subject matter of any of Examples 30-33, and wherein depositing the gate dielectric comprises depositing the gate dielectric with use of atomic layer deposition.

Example 35 includes the subject matter of any of Examples 30-34, and wherein depositing the channel comprises depositing the channel with use of atomic layer deposition.

1. A device comprising:
a source region;
a drain region;
a channel between the source region and the drain region;
a gate electrode; and
a gate dielectric between the gate electrode and the channel, wherein the gate dielectric is ferroelectric, wherein the gate dielectric comprises scandium, aluminum, and nitrogen.

2. The device of claim 1, wherein the channel comprises gallium and nitrogen.

3. The device of claim 1, wherein the channel comprises molybdenum and sulfur.

4. The device of claim 1, wherein the device comprises a transistor, wherein the transistor comprises the source region, the drain region, the channel, the gate dielectric, and the gate electrode, wherein a threshold voltage of the transistor is less than 0.5 volts.

5. The device of claim 1, wherein the device comprises a transistor, wherein the transistor comprises the source region, the drain region, the channel, the gate dielectric, and the gate electrode,
wherein the transistor is a FinFET, a gate-all-around transistor, or a stacked gate-all-around-transistor.

6. A processor comprising the device of claim 1.

7. A system comprising the processor of claim 6 and one or more memory devices.

8. A device comprising:
a transistor, the transistor comprising a gate dielectric, wherein the gate dielectric is ferroelectric, wherein the gate dielectric comprises scandium, aluminum, and nitrogen.

9. The device of claim 8, wherein a threshold voltage of the transistor is less than 0.5 volts.

10. The device of claim 8, wherein the transistor comprises a channel, wherein the channel comprises gallium and nitrogen.

11. The device of claim 8, wherein the transistor comprises a channel, wherein the channel comprises molybdenum and sulfur.

12. The device of claim 8, wherein the transistor is a FinFET, a gate-all-around transistor, or a stacked gate-all-around-transistor.

13. A processor comprising the device of claim 8.

14. A system comprising the processor of claim 13 and one or more memory devices.

15. A device comprising:
a transistor comprising:
a source region;
a drain region;
a channel between the source region and the drain region;
a gate electrode; and
a gate dielectric between the gate electrode and the channel, wherein the gate dielectric comprises scandium, aluminum, and nitrogen,
wherein a threshold voltage of the transistor is less than 0.5 volts.

16. The device of claim 15, wherein the channel comprises gallium and nitrogen.

17. The device of claim 15, wherein the channel comprises molybdenum and sulfur.

18. The device of claim 15, wherein the transistor is a FinFET, a gate-all-around transistor, or a stacked gate-all-around-transistor.

19. A processor comprising the device of claim 15.

20. A method comprising:
depositing a channel of a transistor;
depositing a gate dielectric of the transistor, wherein the gate dielectric and the channel are adjacent, wherein the gate dielectric is ferroelectric, wherein the gate dielectric comprises scandium, aluminum, and nitrogen; and
depositing a gate electrode of the transistor, wherein the gate electrode and the gate dielectric are adjacent.

21. The method of claim 20, wherein a threshold voltage of the transistor is less than 0.5 volts.

22. The method of claim 20, wherein the channel comprises gallium and nitrogen.

23. The method of claim 20, wherein the channel comprises molybdenum and sulfur.

24. The method of claim 20, wherein depositing the gate dielectric comprises depositing the gate dielectric with use of atomic layer deposition.

25. The method of claim 20, wherein depositing the channel comprises depositing the channel with use of atomic layer deposition.
